(19) United States
(12) Patent Application Publication
(10) Pub. No.: US 2024/0200226 A1
(43) Pub. Date: Jun. 20, 2024

(54) PROCESS FOR MANUFACTURING SEMICONDUCTOR WAFERS CONTAINING A GAS-PHASE EPITAXIAL LAYER IN A DEPOSITION CHAMBER

(71) Applicant: SILTRONIC AG, Münich (DE)

(72) Inventors: Ronny Hengst, Brand-Erbisdorf (DE); Joerg Haberecht, Freiberg (DE)

(21) Appl. No.: 18/554,477

(22) PCT Filed: Apr. 4, 2022
(86) PCT No.: PCT/EP2022/058866

§ 371 Date: Oct. 9, 2023

(30) Foreign Application Priority Data
Apr. 13, 2021 (EP) 21168168.9

(51) Int. Cl. C30B 25/16; C30B 25/14; C30B 29/06

(52) U.S. Cl. CPC C30B 25/165; C30B 25/14; C30B 29/06

(57) ABSTRACT

A process produces semiconductor wafers with an epitaxial layer deposited from a gas phase. The process includes: removing material deposited in a deposition chamber from preceding coating operations by etching the deposition chamber; carrying out coating operations in succession, which each entail depositing an epitaxial layer on a substrate wafer in the deposition chamber, including passing a first gas stream of first deposition gas over the substrate wafer to form a semiconductor wafer with the epitaxial layer; and before/after each coating operation, passing a second gas stream of a second deposition gas to an edge region of the substrate/semiconductor wafer. A change is made to a process parameter whose effect is that, through the passing of the second deposition gas, deposition of material in the edge region increases as a function of a number of coating operations carried out since the removal of material from the deposition chamber.

### CROSS REFERENCE TO RELATED APPLICATIONS

This application is a U.S. National Phase application under 35 U.S.C. § 371 of International Application No. PCT/EP2022/058866, filed on Apr. 4, 2022, and claims benefit to European Patent Application No. EP 21168168.9, filed on Apr. 13, 2021. The International Application was published in German on Oct. 20, 2022 as WO 2022/218738 A1 under PCT Article 21(2).

### FIELD

The present disclosure relates to a process for producing semiconductor wafers with epitaxial layer deposited from the gas phase in a deposition chamber.

### BACKGROUND

Semiconductor wafers with epitaxial layer deposited from the gas phase are needed in order to produce electronic components. The epitaxial layer is typically deposited in a deposition chamber in the form of a single-wafer reactor. The substrate wafer for coating is placed on a susceptor, and a deposition gas is passed at a deposition temperature through the deposition chamber over the substrate wafer rotating with the susceptor.

Deposition chambers can enable the establishment of a second gas stream, with a direction different from that of the first gas stream, which primarily brings about the formation of the epitaxial layer.

According to US 2014 0 137 801 A1 a deposition chamber of this kind can be used to establish a second stream of deposition gas.

US 2015 0 368 796 A1 proposes a deposition chamber of this kind for reacting an etching gas with a deposition gas.

JP 2019 114 699 A describes a process which employs a second gas stream in order to influence the effect of the first gas stream.

WO 2017 102 597 A1 is devoted in particular to the problem of improving the edge geometry of a semiconductor wafer with epitaxial layer. It was found that after a typical etch regularly carried out in the deposition chamber (chamber etching) to remove material having deposited in the deposition chamber in the course of preceding coating operations, successive subsequent coating operations result in an increase in edge roll-off in semiconductor wafers with epitaxial layer that are subsequently produced in the deposition chamber. The proposal made is, prior to the deposition of the epitaxial layer, to carry out etching in the presence of the respective substrate wafer to be coated, in order to compensate for a reducing deposition of material in the edge region during the deposition of the epitaxial layer, with the consequence of the increasing edge roll-off. A drawback affecting this proposal is that the etching may result in excessive erosion of material, may see crystal defects in the substrate wafer becoming exposed, and may give rise to particles which contaminate the semiconductor wafer with epitaxial layer.

### SUMMARY

In an embodiment, the present disclosure provides a process that produces semiconductor wafers with an epitaxial layer deposited from a gas phase in a deposition chamber. The process includes: removing, from the deposition chamber, material that has been deposited in the deposition chamber in a course of preceding coating operations by etching of the deposition chamber; carrying out coating operations in succession, which each entail the deposition of an epitaxial layer on a substrate wafer in the deposition chamber, including a first gas stream of first deposition gas being passed over the respective substrate wafer to form a respective semiconductor wafer with the respective epitaxial layer; and before or after each of the coating operations carried out in succession, passing a second gas stream of a second deposition gas to an edge region of the respective substrate wafer or of the respective semiconductor wafer with the respective epitaxial layer. A change is made in at least one process parameter whose effect is that, through the passing of the second deposition gas, deposition of material in the edge region increases as a function of a number of coating operations carried out since the removal of material from the deposition chamber.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows components of a deposition chamber suitable for implementing the process of the present disclosure;

FIG. 2 shows, in plan view, the passing of first and second gas streams to the substrate wafer; and

FIG. 3 and FIG. 4 show the change in the edge geometry as a function of the sequence of deposition of the epitaxial layer after chamber etching.

### DETAILED DESCRIPTION

The present disclosure relates to a process for producing semiconductor wafers with epitaxial layer deposited from the gas phase in a deposition chamber, including the removal from the deposition chamber of material which has deposited in the deposition chamber in the course of preceding coating operations.

Aspects of the present disclosure combat the phenomenon of increasing edge roll-off after chamber etching without having to accept the aforesaid drawbacks.

Aspects of the present disclosure provide a process for producing semiconductor wafers with epitaxial layer deposited from the gas phase in a deposition chamber, comprising:
the removal from the deposition chamber of material which has deposited in the deposition chamber in the course of preceding coating operations, by means of etching of the deposition chamber;
coating operations carried out in succession and each entailing the deposition of an epitaxial layer on a substrate wafer in the deposition chamber, involving a first gas stream of first deposition gas being passed over the substrate wafer, to form a semiconductor wafer with epitaxial layer;
before, during or after each of the coating operations carried out in succession, the passing of a second gas stream of a second deposition gas to an edge region of the respective substrate wafer or of the respective semiconductor wafer with epitaxial layer, wherein a change is made in at least one process parameter whose effect is that through the passing of the second deposition gas, deposition of material in the edge region increases as a function of the number of coating operations carried out since the removal of material from the deposition chamber.

In accordance with an aspect of the present disclosure, a second gas stream of second deposition gas is established, which to a very great extent, compensates the anticipated reducing deposition of material in the edge region from one coating operation to the next, by increasing the deposition of material in the edge region from one coating operation to the next.

The deposition of material brought about by the second deposition gas may take place before, during or after the coating operation which produces the epitaxial layer on the substrate wafer. Because the first and second gas streams may influence one another, the deposition of material by means of the deposition gas is carried out preferably before the deposition of the epitaxial layer on the substrate wafer. It is, however, also possible to bring about the deposition of material by the second deposition gas on the completed semiconductor wafer with epitaxial layer, in other words after the deposition of the epitaxial layer by the first deposition gas. Although deposition of material by the second deposition gas during the deposition of the epitaxial layer is not ruled out, there are advantages to carrying out this deposition of material as a separate process step before or after the deposition of the epitaxial layer. In these cases process control is retained fully and independently of one another both for the coating operation which produces the epitaxial layer and for the processing step which brings about the deposition of material in the edge region. Representing the application of a separate process step, it is assumed below that the deposition of material by the second deposition gas takes place before the respective coating operation. Where appropriate, this separate process step may also include the provision of a first gas stream of carrier gas, hydrogen for example, which is passed over the substrate wafer, as well as the second gas stream of second deposition gas. The respective separate coating operation may also comprise the provision of a second gas stream of carrier gas, which is passed to the edge of the substrate wafer, in order to purge the feed lines, as well as the first gas stream of first deposition gas. For this case the volume velocity of such a second gas stream of carrier gas is preferably less than 5 slm, more preferably less than 3 slm.

The second gas stream of second deposition gas or of carrier gas is passed to the edge region of the substrate wafer located on a susceptor. The second gas stream, accordingly, has a directional component which is directed perpendicularly in the direction of the first gas stream of first deposition gas or of carrier gas.

The first and second deposition gases each contain a precursor gas which comprises the semiconductor that is deposited: for example, a silane such as trichlorosilane. Furthermore, the first deposition gas and the second deposition gas may also comprise a carrier gas, hydrogen for example, and optionally a doping gas, diborane for example. These gases are admixed to the first and, respectively, second gas streams of deposition gas. The doping gas comprises a dopant which is deposited with the semiconductor material. The compositions of the first and second deposition gases may be identical or may differ.

The process conditions under which the second deposition gas is passed to the substrate wafer during the process step differ from one another, specifically depending on the number of coating operations with the first deposition gas that have been carried out since the last chamber etch. The greater this number, the greater the amount of material deposited by the second deposition gas in the edge region of the substrate wafer. The process conditions are adjusted such that the thickness of the material deposited in the edge region very largely compensates the edge roll-off which would be anticipated without the process step after the subsequent coating operation.

Since the anticipated edge roll-off increases from one coating operation to the next, for the process step a change is made in at least one process parameter whose effect is that, in comparison to the preceding process step, a greater amount of material, corresponding to the anticipated increase in the edge roll-off, is deposited in the edge region of the substrate wafer. Suitable process parameters are, for example, the time during which the second deposition gas is passed to the edge region of the substrate wafer, or the velocity with which the second gas stream of second deposition gas is passed to the edge region of the substrate wafer. The longer, for example, the second deposition gas is passed to the edge region of the substrate wafer, the greater the amount of material which will be deposited there. Other suitable process parameters are the volume ratio of precursor gas and carrier gas in the second gas stream of deposition gas, the ratio of the volume velocities of precursor gas and carrier gas before the mixing of these gases to form the second gas stream of deposition gas, the temperature in the deposition chamber, or the velocity with which the substrate wafer is rotated. Optimal harmonization of the process parameters in the sense of the present disclosure is also dependent on the deposition chamber used and possibly on the volume velocity of the carrier gas, if it is used as first gas stream of carrier gas additionally to the second gas stream of deposition gas during a separate process step. This harmonization may be attained by means of trials.

In order to remove from the deposition chamber material which has deposited in the deposition chamber in the course of preceding coating operations, an etching gas—for example hydrogen chloride—is passed through the deposition chamber. Chamber etching of this kind is preferably carried out regularly, when, for example, a deposit of material on an inner surface of the deposition chamber has reached or exceeded a predetermined thickness, or after a predetermined number of coating operations have been carried out. Following the chamber etching, chamber coating may be carried out, by passing, for example, trichlorosilane through the deposition chamber at deposition temperature. This may also take place in the presence of a substrate wafer located on the susceptor, said wafer acting as a dummy to mask the susceptor.

Aspects of the present disclosure are described further below with reference to the drawings.

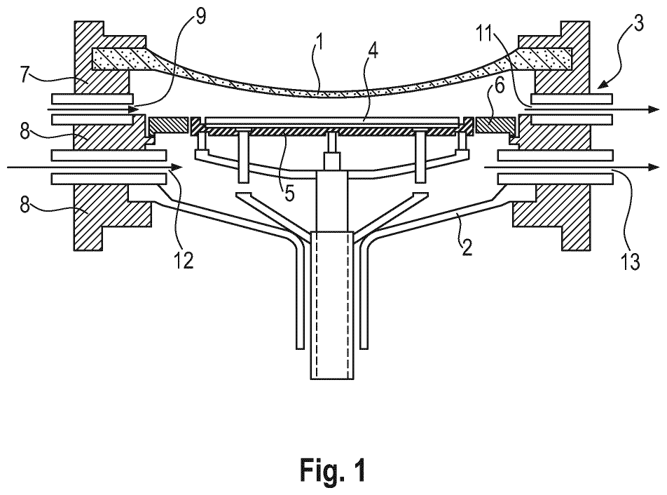

The apparatus shown in FIG. 1 for depositing an epitaxial layer on a substrate wafer comprises a deposition chamber 3 having an upper lid 1 and a lower lid 2, and upper and lower linings 7 and 8, which enclose a reaction space. Upper and lower lamp arrays may be present outside the deposition chamber 3. The radiant energy of the lamps brings the deposition chamber to the temperature which is needed for the gas-phase (vapor) deposition.

For a coating operation, a substrate wafer 4 is placed on a susceptor 5 which is held rotatably from below by arms of a carrier. Arranged around the susceptor is a preheat ring 6. The substrate wafer 4 can be placed on the susceptor 5 and lifted off from the susceptor 5 after coating, by means of lifting rods which pass through the susceptor 5.

In the coating of the substrate wafer 4, the first deposition gas is passed through first gas entry apertures 9, provided in the upper lining 7, into the deposition chamber 3 along a first flow direction over the substrate wafer to a first gas outlet 11. Furthermore, there are one or more second gas entry apertures in the lower lining through which, during a separate process step or during a coating operation, deposition gas is passed along a second flow direction to the edge region of the substrate wafer 4 or of a semiconductor wafer with epitaxial layer. Lastly, as an option, lower gas entry apertures 12 and a lower gas outlet 13 may be provided, in order for a purge gas to be passed under the susceptor 5 through to the lower gas outlet 13.

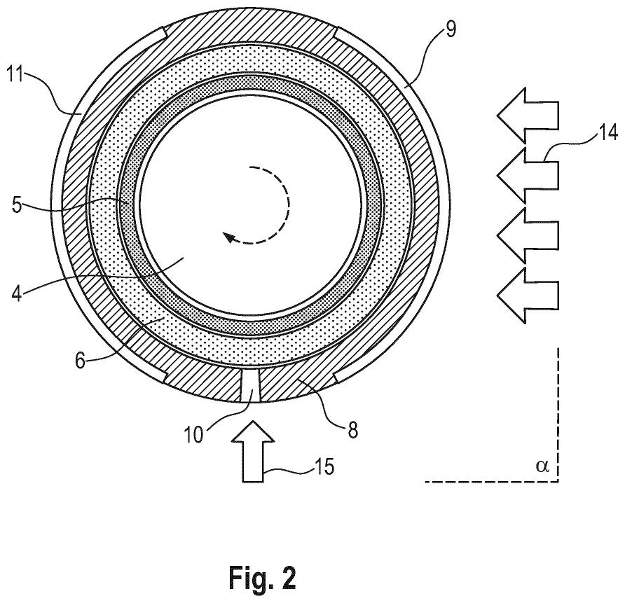

FIG. 2 shows in plan view the passing of a first gas stream 14 over the substrate wafer 4 and of a second gas stream 15 to the edge region of the substrate wafer 4. The second gas stream 15 has a directional component perpendicular to the flow direction of the first gas stream 14. The two flow directions include an angle α which is preferably 45° to 90°. Where a deposition gas is passed in via the second gas stream 15, in the form of a separate process step, it is preferred for a first gas stream 14, consisting of a carrier gas, to be passed simultaneously over the substrate wafer 4 or a semiconductor wafer with epitaxial layer. During a coating operation which is carried out before or after the separate process step, deposition gas is passed over the substrate wafer only via the first gas stream 14, and, optionally, carrier gas is passed to the edge of the substrate wafer via the second gas stream 15. In the absence of a separate process step, both the first gas stream 14 and the second gas stream 15 contain deposition gas.

### EXAMPLE

In a first trial an epitaxial layer of monocrystalline silicon was deposited on each of 25 substrate wafers made of monocrystalline silicon and having a diameter of 300 mm. The coating operations were carried out in the deposition chamber of a single-wafer reactor following chamber etching of the deposition chamber. The design of the single-wafer reactor was such as to allow a first gas stream to be passed over the substrate wafer and a second gas stream to be passed to the edge region of the substrate wafer.

For every second substrate wafer, the coating operation was preceded by a separate process step during which a first gas stream of carrier gas was passed over the substrate wafer and a second gas stream of deposition gas was passed to the edge region of the substrate wafer. The greater the number of coating operations carried out since the chamber etching, the longer the selected time for the supply of the second gas stream of deposition gas. Before coating operations with an even serial number, the separate process step prior to the coating operation was omitted.

After the following coating operation, the edge geometry of the semiconductor wafers with epitaxial layer produced was studied and quantified in the form of the ESFQD_AVG_Δ (Edge Site Front surface least sQuares site Deviation, ESFQD). ESFQD measurements on 72 edge sites (sectors having a length of 30 mm with an edge exclusion of 2 mm, the measurements being made on an area of the sectors having a length between radius 147.5 mm and 148 mm), and for each of these measurements an average (AVG) was calculated for each substrate wafer and each resulting semiconductor wafer with epitaxial layer, and the pair of the two averages was subtracted one from the other (Δ).

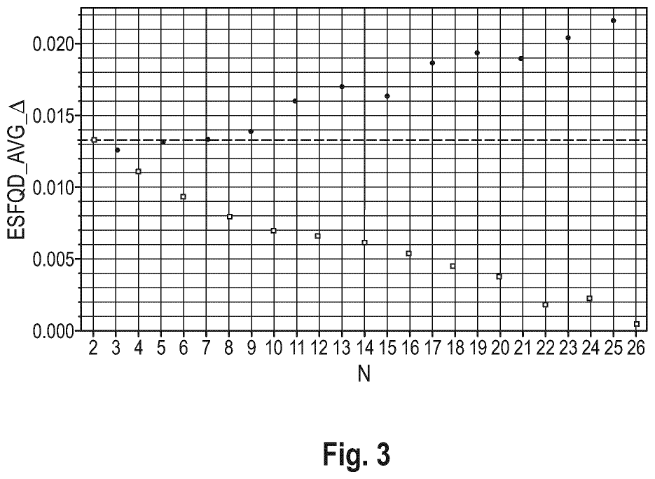

FIG. 3 plots ESFQD_AVG_Δ as the result of the subtraction as a function of the sequence N of coating operations carried out since the chamber etching. Uneven numbers in the sequence are assigned to those substrate wafers coated in accordance with the present disclosure, even numbers to those substrate wafers coated without the separate process step, in other words in the absence of a second gas stream of deposition gas. Furthermore, in the case of a process carried out in accordance with the present disclosure, the time for which the second gas stream of deposition gas was passed to the edge region of the substrate wafer was longer, by a constant amount, than the corresponding time during the process carried out in accordance with the present disclosure immediately before.

The data points falling with even sequence reflect the effect of the increasing edge roll-off after chamber etching in the absence of intervention. The ascending data points with uneven number in the sequence show that the intervention of the present disclosure in some cases more than compensated for the edge roll-off and that even more material than intended was deposited in the edge region.

In a further trial, for coating operations carried out in accordance with the present disclosure with an uneven number in the sequence, the separate process step was omitted; in other words, during the coating operation, the second gas stream of second deposition gas was passed to the edge region of the substrate wafer, a different ratio of the volume velocities of precursor gas and carrier gas was selected before they were mixed to form the second gas stream of deposition gas, and the time of the coating operation was shortened in comparison with the time thereof in the first trial.

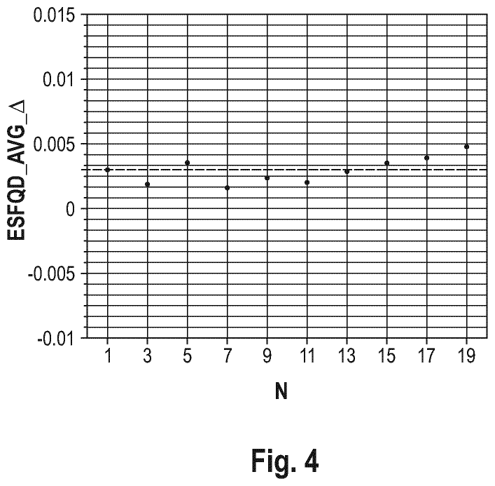

FIG. 4 shows that, with the selected combination of process parameters, it was possible to achieve a comparatively uniform edge geometry of the semiconductor wafers with epitaxial layer.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS USED

1 upper lid
2 lower lid
3 deposition chamber
4 substrate wafer
5 susceptor
6 preheat ring
7 upper lining
8 lower lining
9 first gas entry apertures
10 gas entry aperture for the second gas stream
11 first gas outlet
12 lower gas entry apertures
13 lower gas outlet
14 first gas stream
15 second gas stream

1-2. (canceled)

3. A process for producing semiconductor wafers with an epitaxial layer deposited from a gas phase in a deposition chamber, the process comprising:
removing, from the deposition chamber, material that has been deposited in the deposition chamber in a course of preceding coating operations by etching of the deposition chamber;
carrying out coating operations in succession, which each entail the deposition of an epitaxial layer on a substrate wafer in the deposition chamber, comprising a first gas stream of first deposition gas being passed over the respective substrate wafer to form a respective semiconductor wafer with the respective epitaxial layer; and
before or after each of the coating operations carried out in succession, passing a second gas stream of a second deposition gas to an edge region of the respective substrate wafer or of the respective semiconductor wafer with the respective epitaxial layer, wherein a change is made in at least one process parameter whose effect is that, through the passing of the second deposition gas, deposition of material in the edge region increases as a function of a number of coating operations carried out since the removal of material from the deposition chamber.

4. The process as claimed in claim 3, wherein the at least one process parameter is selected from a group which comprises: a time during which the second gas stream of second deposition gas is passed to the substrate wafer, a velocity with which the second deposition gas is passed to the edge region of the substrate wafer, a volume ratio of a precursor gas and a carrier gas in the second gas stream, a ratio of the volume velocities of the precursor gas and the carrier gas before mixing of these gases to form the second gas stream, a temperature in the deposition chamber, and a velocity with which the substrate wafer is rotated.

5. The process as claimed in claim 3, wherein the passing of the first gas stream along a first flow direction and by the passing of the second gas stream along a second flow direction, wherein the first flow direction and the second flow direction comprise an angle α which is 45° to 90°.
